(19) United States
(12) Patent Application Publication
(10) Pub. No.: US 2011/0199346 A1
(43) Pub. Date: Aug. 18, 2011

(54) SEMICONDUCTOR DEVICE HAVING GUARD RING, DISPLAY DRIVER CIRCUIT, AND DISPLAY APPARATUS

(75) Inventors: Jae Hyok Ko, Hwaseong-si (KR); Han Gu Kim, Seongnam-si (KR); Chang Su Kim, Suwon-si (KR); Suk-Jin Kim, Hwaseong-si (KR); Kwan Young Kim, Seoul (KR)

(73) Assignee: Samsung Electronics Co., Ltd.

(21) Appl. No.: 13/025,754

(22) Filed: Feb. 11, 2011

(30) Foreign Application Priority Data
Feb. 12, 2010 (KR) 10-2010-0013375
Dec. 29, 2010 (KR) 10-2010-0138259

(51) Int. Cl. G06F 3/038; H01L 27/082; H01L 21/8222

(52) U.S. Cl. 345/204; 257/503; 438/353; 257/E27.053; 257/E21.608

(57) ABSTRACT

A semiconductor device includes a semiconductor substrate having a first conductivity type, at least two first well regions which have a second conductivity type and a predetermined depth in the semiconductor substrate, at least one second well region which has the first conductivity type and a predetermined depth in each of the first well regions, and a guard-ring region which has the second conductivity type and a predetermined depth and is positioned between the first well regions to be separated by a predetermined distance from the first well regions. The guard-ring region is connected to a ground voltage.

### CROSS-REFERENCE TO RELATED APPLICATIONS

This application claims the benefit of Korean Patent Application Nos. 10-2010-0013375, filed on Feb. 12, 2010 and 10-2010-0138259, filed on Dec. 29, 2010 in the Korean Intellectual Property Office, the disclosures of which are incorporated by reference herein in their entireties.

### BACKGROUND

The present invention relates to a semiconductor device having a guard ring, a display driver, and a display apparatus, and more particularly, to a semiconductor device having a guard ring for discharging a charge into a system ground, a display driver including the same, and a display apparatus including the display driver.

Display Port-based apparatuses have to undergo an electrostatic discharge (ESD) test defined in an International Electrotechnical Commission (IEC) 61000-4-2 standard. For instance, mobile phones having lots of contact with hands must undergo the level 4 or higher test. When charges are emitted to a target apparatus using a test machine during a test, the charges are injected to a semiconductor device in a display driver included in the apparatus. At this time, conventionally, the semiconductor device may be permanently damaged or subjected to logic abnormality by the injected charges due to its structure.

### SUMMARY

Some embodiments of the present invention provide a semiconductor device having a structure for minimizing permanent damage or abnormality, a display driver circuit including the same, and a display apparatus including the display driver circuit.

According to some embodiments of the present invention, there is provided a semiconductor device including a semiconductor substrate having a first conductivity type, at least two first well regions which have a second conductivity type and a predetermined depth in the semiconductor substrate, at least one second well region which has the first conductivity type and a predetermined depth in each of the first well regions, and a guard-ring region which has the second conductivity type and a predetermined depth and is positioned between the first well regions to be separated by a predetermined distance from the first well regions. The guard-ring region may be connected to a ground voltage.

The guard-ring region may be deeper than the first well regions. Each of the first well regions may include an N+ layer on its surface. The second well region may include a P+ region on its surface. The guard-ring region may include an N+ layer on its surface.

The semiconductor device may further include a P+ layer on a surface of the semiconductor substrate between the first well regions and the guard-ring region.

The N+ layer on the surface of each of the first well regions, the P+ layer on the surface of the second well region, and the N+ layer on the surface of the guard-ring region may be respectively connected to electrodes. The electrode connected to the N+ layer on the surface of the guard-ring region may be connected to the ground voltage. Charges may be injected to one of electrodes connected to the N+ layers on the surfaces of the respective first well regions.

The first conductivity type may be a P type and the second conductivity type may be an N type.

According to other embodiments of the present invention, there is provided a method of fabricating a semiconductor device. The method includes the operations of forming at least two second conductivity type first well regions to a predetermined depth from a surface of a first conductivity type semiconductor substrate, forming at least one first conductivity type second well region having a predetermined depth in each of the first well regions, forming a second conductivity type guard-ring region between the first well regions to be separated by a predetermined distance from the first well regions and to have a predetermined depth, and connecting the guard-ring region to a ground voltage.

The operation of forming the guard-ring region may include forming the guard-ring region to be deeper than the first well regions.

### BRIEF DESCRIPTION OF THE DRAWINGS

The above and other features and advantages of the present invention will become more apparent by describing in detail exemplary embodiments thereof with reference to the attached drawings in which:

FIG. 1 is a diagram of a semiconductor device according to some embodiments of the present invention;

FIG. 2 is a diagram of a semiconductor device according to other embodiments of the present invention;

FIG. 3 is a graph showing the changes in voltages of electrodes of a semiconductor device having no guard-ring region over time;

FIG. 4 is a graph showing the changes in voltages of electrodes of a semiconductor device having a guard-ring region over time;

FIG. 5 is a flowchart of a method of fabricating a semiconductor device according to some embodiments of the present invention;

FIG. 6A is a diagram of a display apparatus according to some embodiments of the present invention;

FIG. 6B is a diagram of a system including the display apparatus illustrated in FIG. 6A;

FIG. 6C is a diagram showing a procedure in which charges are transmitted to the semiconductor device illustrated in FIG. 1 or 2.

FIG. 7 is a diagram of a semiconductor chip according to some embodiments of the present invention; and

FIGS. 8A and 8B are diagrams of a semiconductor device for implementing the semiconductor chip illustrated in FIG. 7.

### DETAILED DESCRIPTION OF THE EMBODIMENTS

The present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. Like numbers refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms first, second, etc. may be used herein to describe various elements, these elements should not be limited by these terms. These terms are only used to distinguish one element from another. For example, a first signal could be termed a second signal, and, similarly, a second signal could be termed a first signal without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

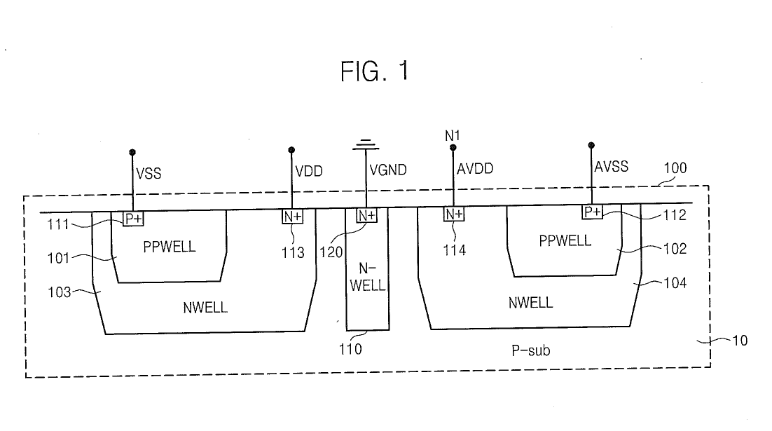

FIG. 1 is a diagram of a semiconductor device 100 according to some embodiments of the present invention. The semiconductor device 100 includes a P-type semiconductor substrate 10. N-type first well regions 103 and 104 having a predetermined depth are formed on a surface of the P-type semiconductor substrate 10 to be separated by a predetermined distance from each other. N+ layers 113 and 114 are formed on surfaces of the first well regions 103 and 104, respectively.

Second well regions 101 and 102 having a predetermined depth are formed in the first well regions 103 and 104, respectively. P+ layers 111 and 112 are formed on surfaces of the second well regions 101 and 102, respectively. The second well regions 101 and 102 may be PP wells. The N+ layers 113 and 114 are not included in the second well regions 101 and 102. The N+ layers 113 and 114 and the P+ layers 111 and 112 are respectively connected to electrodes VDD, AVDD, VSS, and AVSS.

The semiconductor device 100 includes an N-type guard-ring region 110 having a predetermined depth between the first well regions 103 and 104. The guard-ring region 110 is separated by a predetermined distance from each of the first well regions 103 and 104. The guard-ring region 110 includes an N+ layer 120 on its surface. The N+ layer 120 is connected to an electrode VGND connected to a system ground voltage.

The guard-ring region 110, the semiconductor substrate 10, and the first well region 104 forms a parasitic NPN bipolar transistor having the guard-ring region 110 as an emitter, the semiconductor substrate 10 as a base, and the first well region 104 as a collector.

When charges are emitted to a display apparatus (e.g., a display panel) using a machine performing an electrostatic discharge (ESD) test, the charges are injected to a node N1 connected to the panel, thus raising the voltage of the electrode AVDD. As a result, a breakdown occurs and holes moves from the first well region 104 to the semiconductor substrate 10. However, the semiconductor device 100 including the guard-ring region 110 having the predetermined depth prevents the holes from moving to the first well region 103 and raising the voltage of the electrode VDD.

If the guard-ring region 110 is not provided, the semiconductor device 100 will have a parasitic NPN bipolar transistor having the first well region 103 as an emitter, the semiconductor substrate 10 as a base, and the first well region 104 as a collector. When a breakdown occurs, the charges injected to the semiconductor device 100 by the ESD test machine move to the first well region 103 and thus raise the voltage of the electrode VDD, thereby causing a permanent damage or abnormality in the semiconductor device 100.

The guard-ring region 110 may be deeper than the first well regions 103 and 104. At this time, the holes may be more efficiently flow into the guard-ring region 110.

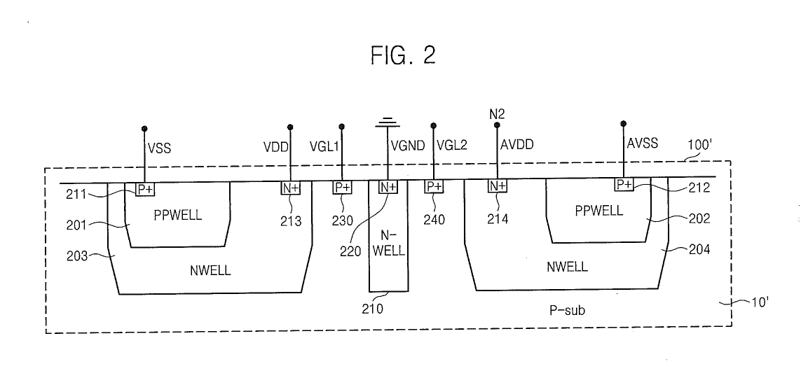

FIG. 2 is a diagram of a semiconductor device 100′ according to other embodiments of the present invention. The semiconductor device 100′ includes a P-type semiconductor substrate 10′. N-type first well regions 203 and 204 having a predetermined depth are formed on a surface of the P-type semiconductor substrate 10′ to be separated by a predetermined distance from each other. N+ layers 213 and 214 are formed on surfaces of the first well regions 203 and 204, respectively.

Second well regions 201 and 202 having a predetermined depth are formed in the first well regions 203 and 204, respectively. P+ layers 211 and 212 are formed on surfaces of the second well regions 201 and 202, respectively. The second well regions 201 and 202 may be PP wells. The N+ layers 213 and 214 are not included in the second well regions 201 and 202.

The semiconductor device 100′ includes an N-type guard-ring region 210 having a predetermined depth between the first well regions 203 and 204. The guard-ring region 210 is separated by a predetermined distance from each of the first well regions 203 and 204. The guard-ring region 210 includes an N+ layer 220 on its surface. The N+ layer 220 is connected to an electrode VGND connected to a system ground voltage.

The semiconductor substrate 10′ includes P+ layers 230 and 240 on its surface. The P+ layer 230 is positioned between the guard-ring region 210 and the first well region 203 and the P+ layer 240 is positioned between the guard-ring region 210 and the first well region 204. The P+ layers 230 and 240 may be separated by a predetermined distance from the guard-ring region 210 and the first well regions 203 and 204.

The N+ layers 213 and 214 and the P+ layers 211, 212, 230, and 240 are respectively connected to electrodes VDD, AVDD, VSS, AVSS, VGL1, and VGL2. At this time, the electrodes VGL1 and VGL2 may correspond to the same node.

The guard-ring region 210, the semiconductor substrate 10′, and the first well region 204 forms a parasitic NPN bipolar transistor having the guard-ring region 210 as an emitter, the semiconductor substrate 10′ as a base, and the first well region 204 as a collector.

When charges are emitted to a display apparatus (e.g., a display panel) using an ESD test machine, the charges are injected to a node N2 connected to the panel, thus raising the voltage of the electrode AVDD. As a result, a breakdown occurs and holes moves from the first well region 204 to the semiconductor substrate 10′. However, the semiconductor device 100′ including the guard-ring region 210 having the predetermined depth prevents the holes from moving to the first well region 203 and raising the voltage of the electrode VDD.

If the guard-ring region 210 is not provided, the semiconductor device 100′ will have a parasitic NPN bipolar transistor having the first well region 203 as an emitter, the semiconductor substrate 10′ as a base, and the first well region 204 as a collector. When a breakdown occurs, the charges injected to the semiconductor device 100′ by the ESD test machine move to the first well region 203 and thus raise the voltage of the electrode VDD, thereby causing a permanent damage or abnormality in the semiconductor device 100′.

The guard-ring region 210 may be deeper than the first well regions 203 and 204. At this time, the holes may be more efficiently flow into the guard-ring region 210. The conductivity types used in the semiconductor devices 100 and 100′ are not restricted to the embodiments illustrated in FIGS. 1 and 2 and they can be vice versa. For instance, N types may be changed to P types and P types may be changed to N types.

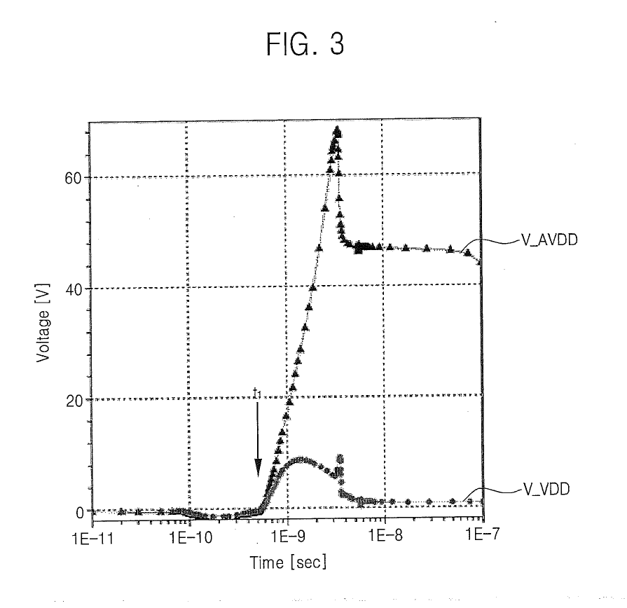

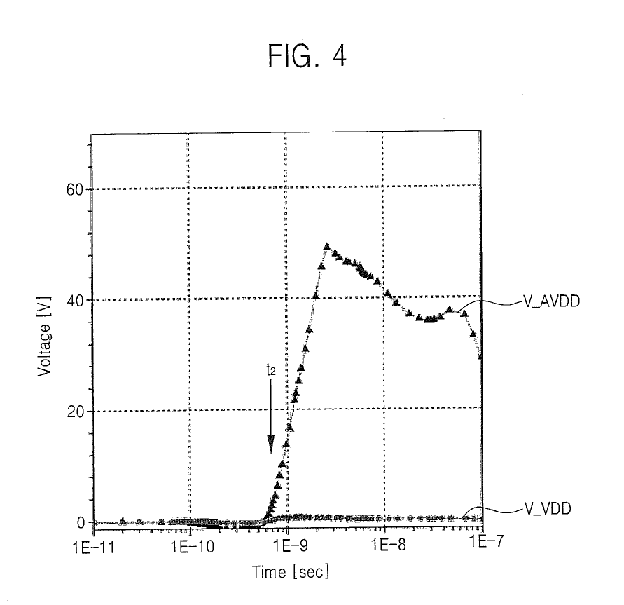

FIG. 3 is a graph showing the changes in voltages of electrodes of a semiconductor device having no guard-ring region over time. FIG. 4 is a graph showing the changes in voltages of electrodes of the semiconductor device 100 according to some embodiments of the present invention.

Referring to FIG. 3, when charges are injected to the semiconductor device that does not have a guard-ring region at a time point t1, a voltage V_AVDD of an electrode AVDD increases and a voltage V_VDD of an electrode VDD increases above about 8 V due to the inflow of holes. At this time, the semiconductor device that does not have a guard-ring region is assumed to be the semiconductor device 100 illustrated in FIG. 1 from which the guard-ring region 110 is removed. If the electrode VDD of the semiconductor device has an allowable voltage of 6 V, the semiconductor device may have troubles.

Referring to FIG. 4, when charges are injected to the semiconductor device 100 including the guard-ring region 110 at a time point t2, a voltage V_AVDD of the electrode AVDD increases, but a voltage V_VDD of the electrode VDD rarely increases since holes are taken into the guard-ring region 110. If the electrode VDD of the semiconductor device 100 has an allowable voltage of 6 V, the semiconductor device 100 does not have any trouble since the voltage V_VDD of the electrode VDD increases only up to about 0.5 V.

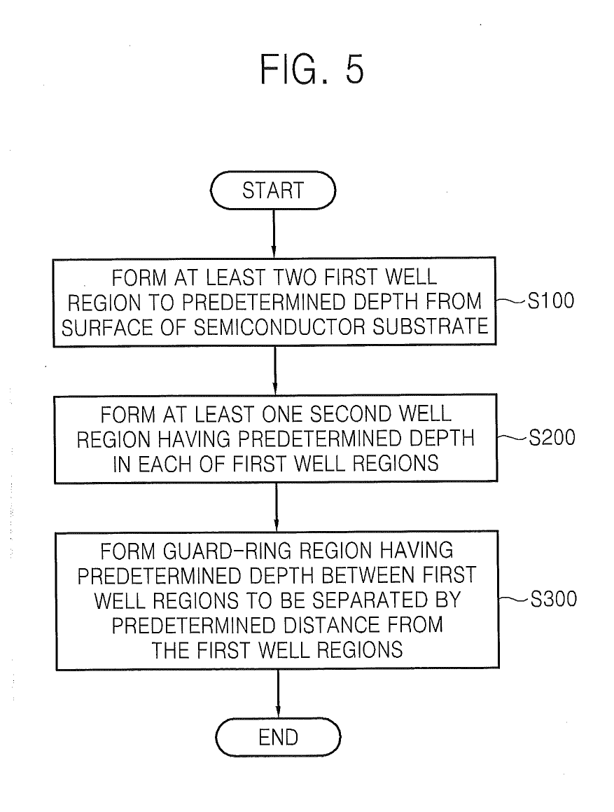

FIG. 5 is a flowchart of a method of fabricating a semiconductor device according to some embodiments of the present invention. At least two first well regions are formed to a predetermined depth from a surface of a semiconductor substrate in operation S100. At this time, the semiconductor substrate may have a P-type conductivity and the first well regions may have an N-type conductivity. In addition, the first well regions may be separated by a predetermined distance from each other.

Next, at least one second well region having a predetermined depth is formed in each of the first well regions in operation 5200. Thereafter, a guard-ring region having a predetermined depth is formed between the first well regions to be separated by a predetermined distance from the first well regions in operation S300. At this time, the guard-ring region may be formed deeper than the first well regions. In addition, the guard-ring region may be connected to a system ground voltage.

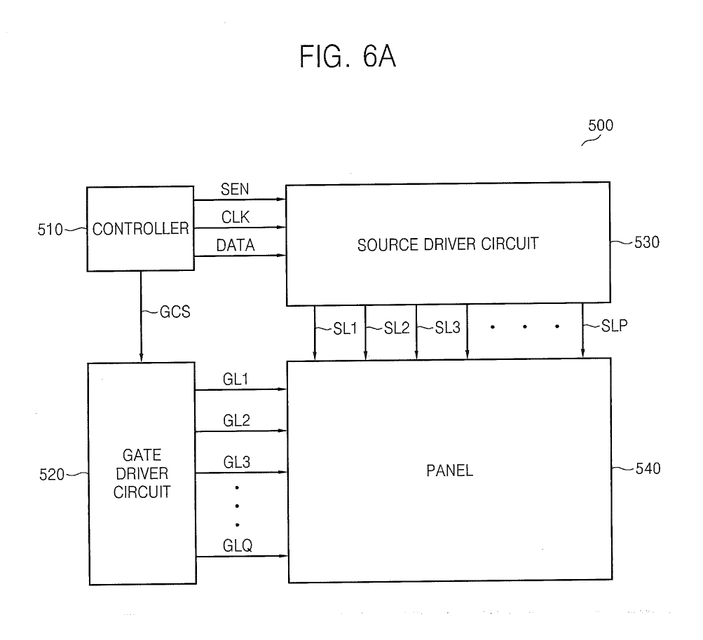

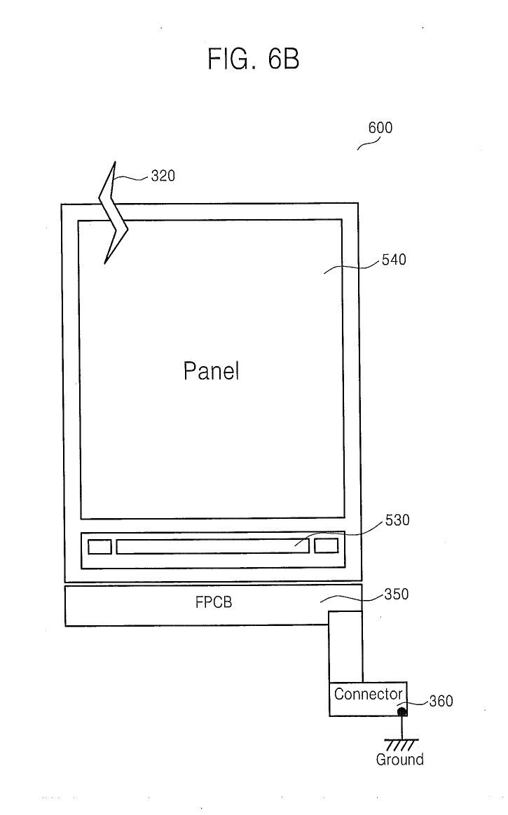

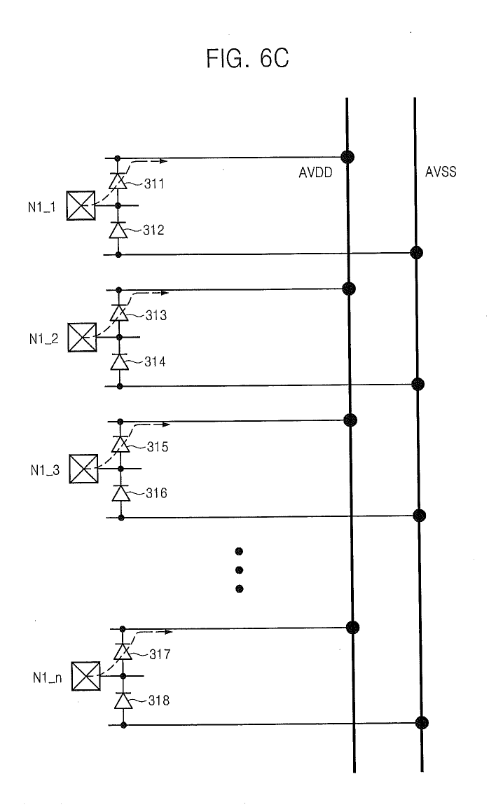

FIG. 6A is a diagram of a display apparatus 500 according to some embodiments of the present invention. The display apparatus 500 includes a controller 510, a gate driver circuit 520, a source driver circuit or display driver circuit 530, and a panel 540.

The controller 510 provides a gate control signal GCS to the gate driver circuit 520 and provides an enable signal SEN, a system clock signal CLK, and data signal DATA to the source driver circuit 530. The gate driver circuit 520 provides a gate signal to gate lines GL1, GL2, . . . , and GLQ.

The source driver circuit 530 includes the semiconductor device 100 or 100′ illustrated in FIG. 1 or 2 and provides the data signal DATA to source lines SL1, SL2, . . . , and SLP. The source driver circuit 530 may include a plurality of source drivers. While one of the source drivers may receive data since the enable signal SEN is applied to the source driver, the other source drivers may not receive data since the enable signal SEN is not applied to the source drivers.

The panel 540 includes a plurality of pixels respectively formed at intersections between the gate lines GL1 through GLQ and the source lines SL1 through SLQ and displays the data signal DATA.

FIG. 6B is a diagram of a system 600 including the display apparatus 500 illustrated in FIG. 6A. Referring to FIG. 6B, the system 600 includes the display apparatus 500 and a flexible printed circuit board (FPCB) 350. The system 600 is connected to a system ground voltage through a connector 360, and therefore, the guard-ring region 110 and 210 illustrated in FIGS. 1 and 2 can be connected to the system ground voltage. Charges emitted by an ESD test machine may flow into the system 600, as denoted by reference numeral 320, and therefore, the charges may flow into the source driver circuit 530.

FIG. 6C is a diagram showing a procedure in which charges emitted by the ESD test machine flow into the source driver circuit 530 and are thus transmitted to the semiconductor device 100 or 100′ illustrated in FIG. 1 or 2. Each of nodes N1_1 through N1_n illustrated in FIG. 6C may correspond to the node N1 or N2 illustrated in FIG. 1 or 2.

When charges are emitted by the ESD test machine to the panel 540, the charges flow into the nodes N1_1 through N1_n connected to the panel 540. The charges are transmitted to electrodes AVDD through forward diodes 311, 313, 315, and 317 respectively connected to the nodes N1_1 through N1_n. At this time, the charges may be positive charges and are not directly applied to electrodes AVSS due to backward diodes 312, 314, 316, and 318 respectively connected to the nodes N1_1 through N1_n.

Accordingly, permanent damage or logic abnormality is prevented from occurring due to charges injected by an ESD test machine.

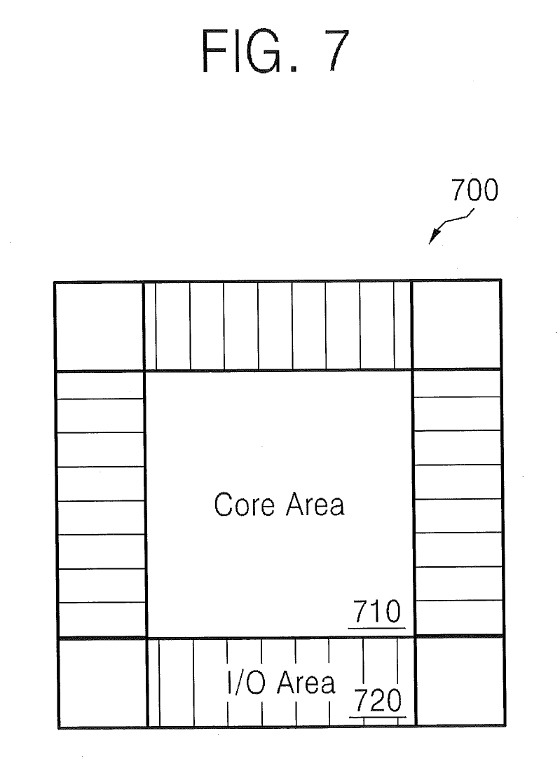

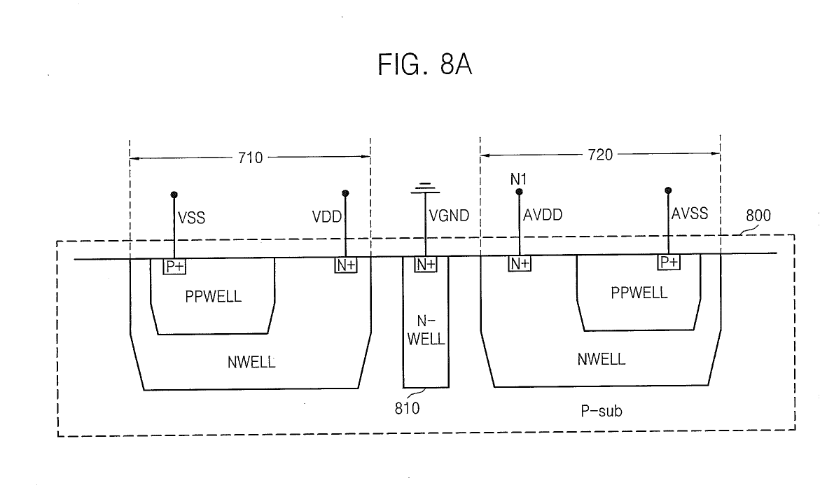

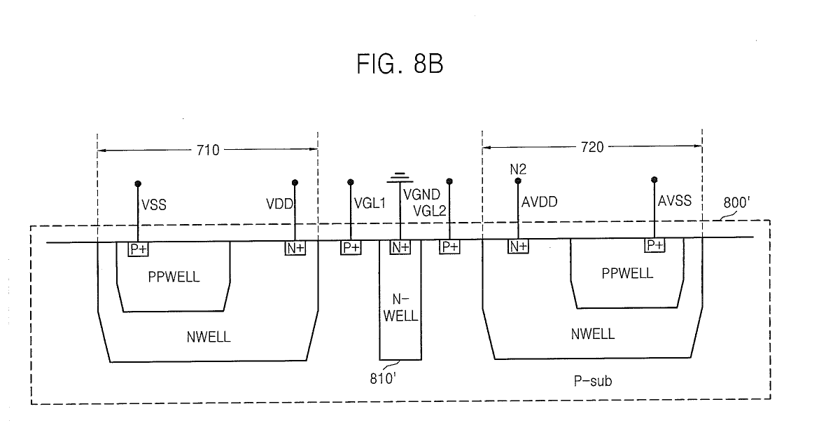

FIG. 7 is a diagram of a semiconductor chip according to some embodiments of the present invention. FIGS. 8A and 8B are diagrams of a semiconductor device for implementing the semiconductor chip illustrated in FIG. 7.

Referring to FIG. 7, a semiconductor chip 700 includes a core area 710 and an input/output (I/O) area 720. The core area 710 performs main processes and may include integrated circuits for performing the processes. The I/O area 720 functions as an interface for inputting and outputting signals. The I/O area 720 may be positioned at the edge of the core area 710 to input signals to and output signals from the core area 710. There may be a marginal space between the core area 710 and the I/O area 720.

Semiconductor devices 800 and 800′ illustrated in FIGS. 8A and 8B have the same structures as the semiconductor devices 100 and 100′ illustrated in FIGS. 1 and 2, respectively. As illustrated in FIGS. 8A and 8B, the semiconductor chip 700 illustrated in FIG. 7 may be implemented using either of the semiconductor devices 800 and 800′.

In detail, the semiconductor devices 800 and 800′ may manifest the core area 710 and the I/O area 720 around the guard-ring regions 810 and 810′, respectively. The guard-ring regions 810 and 810′ may be connected to a system ground voltage of 0 V.

In the embodiments illustrated in FIGS. 7 through 8B, the guard-ring regions 810 and 810′ are provided between the core area 710 and the I/O area 720, but the present invention is not restricted to these embodiments. For instance, a semiconductor device according to the present invention may be applied to all cases for preventing ESD coupling between blocks such as the core area 710 and the I/O area 720.

As described above, according to some embodiments of the present invention, a semiconductor device having a structure different from conventional semiconductor devices is provided by introducing a guard ring, thereby minimizing permanent damage or abnormality to the semiconductor device.

As described above, according to some embodiments of the present invention, a guard ring is provided for a semiconductor device, thereby preventing permanent damage or logic abnormality from occurring in the semiconductor device when charges are injected by an ESD test machine to the semiconductor device.

While the present invention has been particularly shown and described with reference to exemplary embodiments thereof, it will be understood by those of ordinary skill in the art that various changes in forms and details may be made therein without departing from the spirit and scope of the present invention as defined by the following claims.

What is claimed is:

1. A semiconductor device comprising:
a semiconductor substrate having a first conductivity type;
at least two first well regions which have a second conductivity type and a predetermined depth in the semiconductor substrate;
at least one second well region which has the first conductivity type and a predetermined depth in each of the first well regions; and
a guard-ring region which has the second conductivity type and a predetermined depth and is positioned between the first well regions to be separated by a predetermined distance from the first well regions,
wherein the guard-ring region is connected to a ground voltage.

2. The semiconductor device of claim 1, wherein the guard-ring region is deeper than the first well regions.

3. The semiconductor device of claim 2, wherein each of the first well regions comprises an N+ layer on a surface of the each of the first well regions, the second well region comprises a P+ region on a surface of the second well region, and the guard-ring region comprises a N+ layer on a surface of the guard-ring region.

4. The semiconductor device of claim 3, further comprising a P+ layer on a surface of the semiconductor substrate between the first well regions and the guard-ring region.

5. The semiconductor device of claim 3, wherein the N+ layer on the surface of each of the first well regions, the P+ layer on the surface of the second well region, and the N+ layer on the surface of the guard-ring region are respectively connected to electrodes.

6. The semiconductor device of claim 5, wherein the electrode connected to the N+ layer on the surface of the guard-ring region is connected to the ground voltage.

7. The semiconductor device of claim 5, wherein charges are injected to one of electrodes connected to the N+ layers on the surfaces of the respective first well regions.

8. The semiconductor device of claim 1, wherein the first conductivity type is a P type and the second conductivity type is an N type.

9. A display driver circuit comprising the semiconductor device of claim 1.

10. A display apparatus comprising the display driver circuit of claim 9.

11. A method of fabricating a semiconductor device, the method comprising the operations of:
forming at least two second conductivity type first well regions having a predetermined depth from a surface of a first conductivity type semiconductor substrate;
forming at least one first conductivity type second well region having a predetermined depth in each of the first well regions;
forming a second conductivity type guard-ring region between the first well regions to be separated by a predetermined distance from the first well regions and to have a predetermined depth; and
connecting the guard-ring region to a ground voltage.

12. The method of claim 11, wherein the operation of forming a second conductivity type guard-ring region comprises forming the guard-ring region to be deeper than the first well regions.

13. The method of claim 11, wherein the operation of forming at least two second conductivity type first well regions comprises forming an N+ layer on a surface of the each of the first well regions.

14. The method of claim 13, wherein the operation of forming at least one first conductivity type second well region comprises forming a P+ region on a surface of the second well region.

15. The method of claim 14, wherein the operation of forming a second conductivity type guard-ring region comprises forming an N+ layer on a surface of the guard-ring region.

16. The method of claim 15, wherein the N+ layer on the surface of each of the first well regions, the P+ layer on the surface of the second well region, and the N+ layer on the surface of the guard-ring region are respectively connected to electrodes.

17. The method of claim 11, wherein The method further comprising forming a P+ layer on the semiconductor substrate between the first well regions and the guard-ring region.

18. The method of claim 16, wherein connecting the guard-ring region comprising connecting the electrodes connected in the N+ layer on the surface of the guard-ring region to a ground voltage.

19. A semiconductor device comprising:
a first circuit area;
a second circuit area; and
a guard-ring region disposed between the first circuit area and the second circuit area to be separated from the first and second circuit areas by a predetermined distance and formed to a predetermined depth,
wherein the guard-ring region is connected to a ground voltage.

20. The semiconductor device of claim 19, wherein the first circuit area is a core area and the second circuit area is an input/output area.
